(19) United States
(12) Patent Application Publication
(10) Pub. No.: US 2007/0030568 A1
(43) Pub. Date: Feb. 8, 2007

(54) High-reflectance visible-light reflector member, liquid-crystal display backlight unit employing the same, and manufacture of the high-reflectance visible-light reflector member

(75) Inventors: Tadahiro Ohmi, Miyagi (JP); Tetsuya Goto, Miyagi (JP); Nobuaki Seki, Miyagi (JP); Satoshi Ikeda, Tokyo (JP); Kouichi Niikura, Tokyo (JP)

Correspondence Address: FOLEY AND LARDNER LLP;SUITE 500, 3000 K STREET NW, WASHINGTON, DC, 20007, US

(73) Assignee: TOHOKU UNIVERSITY FUTURE VISION INC.

(21) Appl. No.: 11/492,217

(22) Filed: Jul. 25, 2006

(30) Foreign Application Priority Data
Jul. 26, 2005 (JP) 2005-215404

(51) Int. Cl. G02B 1/10; F21V 9/04; G02F 1/1335; B32B 17/06; C23C 14/00; C23C 14/32

(52) U.S. Cl. 359/584; 204/192.1; 204/192.27; 359/360; 359/585; 428/432; 349/113

(57) ABSTRACT

A reflector member of the present invention includes a silver thin film formed on a substrate and a silicon nitride protection film formed on the silver thin film. The silver thin film has the (111) orientation as the principal plane orientation. Preferably, 99% or more of the silver thin film has the (111) orientation as the principal plane orientation. The thickness of the silver thin film is in a range of 100 nm to 350 nm.

This application claims priority to prior Japanese patent application JP 2005-215404, the disclosure of which is incorporated herein by reference.

### BACKGROUND OF THE INVENTION

The present invention relates to a reflector member for reflecting visible light, and in particular to a visible-light reflector member suitable as a reflecting plate for use in a backlight unit of a large-size flat-panel liquid-crystal display having a screen width across corners of 28 inches or greater, or as a reflector member for use in a rear projection television.

The reflecting plates for reflecting visible light includes diffusive reflecting plates applied with white paint or those containing diffusion beads, polished metal plates, and reflecting plates fabricated by depositing metallic atoms on a substrate to form thin films.

These visible-light reflecting plates are used in a variety of applications, such as reflecting plates for liquid crystal display backlight units or rear projection televisions, reflecting plates for interior fluorescent lamps, reflecting layers in recording media such as CDs and DVDs, and external and interior mirrors of vehicles.

The light reflected by the diffusive reflecting plates has no directivity due to diffuse reflection. This is advantageous because it reduces variation in brightness in a liquid crystal display screen. However, as the reflected light has no directivity, much light is lost when reflected by a wall or the like, resulting in poor use efficiency. Therefore, when a diffusive reflecting plate is used in a flat-panel display having a screen width across corners of 30 inches, for example, at least twelve cold cathode fluorescent lamps (CCFLs) have to be used for providing brightness, and this leads to a disadvantage of increasing electric power consumption. In order to minimize the number of arranged CCFLs to reduce the power consumption, there is a demand for reflecting plates capable of controlling the light-reflecting direction (light directivity) and enabling efficient use.

There is also a demand in the rear projection television industry for highly reflecting plates possessing directivity in order to improve the screen brightness and reduce the power consumption.

It is necessary for obtaining reflected light having directivity to use a metallic surface to reflect the light. It has been scientifically demonstrated that a metallic reflecting plate reflects light such that an angle formed between the incoming direction of light and the perpendicular to the reflection plane, namely an angle of incidence, is equal to an angle formed between the outgoing direction of light and the perpendicular to the reflection plane, or an angle of emergence. Thus, the reflection direction is freely controllable based on a design of the reflection plane.

Aluminum or silver is typically used for reflection of visible-light region. Copper and gold are not preferable because they themselves have a property to absorb short-wavelength light, resulting in giving a color to the reflected light. Comparing aluminum with silver, it is reported that, when they are vapor deposited to form a thin film, for example, the silver film exhibits about 98% reflectance at 550-nm wavelength, whereas the aluminum exhibits about 91% reflectance. Thus, silver exhibits higher reflectance than aluminum.

However, a vapor-deposited silver film has a problem that its reflectance is somewhat lowered in the short wavelength side of the visible-light region. For example, it is reported that, at 430-nm wavelength, silver and aluminum exhibit 95% and 92% reflectance, respectively. Although silver has higher reflectance than aluminum as for these values, the reflectance of silver at this wavelength is relatively lower when compared with that at 550-nm wavelength. Additionally, silver has a disadvantage that the durability is lower than that of aluminum. This means that, when exposed to atmosphere, silver is susceptible to reaction such as oxidization or sulfidization, leading to reduction of reflectance.

### SUMMARY OF THE INVENTION

It is therefore an object of the present invention to provide a visible-light reflector member or reflective film having higher reflectance than a conventional silver thin-film reflecting plate particularly in the low wavelength side of visible light, and having high durability.

It is another object of the present invention to provide a method of manufacturing a visible-light reflector member or reflective film having high reflectance in the low wavelength side of visible light and having high durability.

It is still another object of the present invention to provide a visible-light reflecting plate or reflective film having high durability and suitable for use in a large-size reflecting plate such as one for use in a backlight unit of a large-size flat-panel liquid crystal display.

It is yet another object of the present invention to provide a high reflectance visible-light reflecting plate or reflective film having high durability for use as a reflecting plate in a rear projection television.

As a result of painstaking research on relationship between plane orientations and visible-light reflectance of silver, the present inventors have found that, when a silver thin film is covered with a thin film of a specific nitride, namely silicon nitride, the reduction of reflectance is substantially prevented and, moreover, the deterioration with time in reflectance is prevented. Furthermore, the inventors have found that, when a silver thin film is formed by sputtering while controlling the ion irradiation energy to the substrate, the silver thin film, a large part of which has a (111) plane orientation of a silver crystal, exhibits improved reflectance for visible light particularly in the blue wavelength region having a short wavelength of about 400 nm.

The present invention therefore provides a reflector member including a silver thin film formed on a substrate and a silicon nitride film formed on the silver thin film.

The silver thin film has the (111) orientation as the principal plane orientation and, desirably, 99% or more of the silver thin film has the (111) orientation as the principal plane orientation.

Desirably, the silver thin film has a reflectance of 96% or more at a wavelength of 430 nm.

The silver thin film desirably has a thickness in the range of 100 nm to 350 nm.

The silicon nitride film desirably has a thickness in the range of 5 nm to 8 nm.

When the substrate is formed of a plastic material, the plastic material desirably has a thickness of 0.7 mm to 2 mm.

The substrate can be formed of a flexible resin to provide a film-shaped reflector member. When formed of a flexible resin, the substrate desirably has a thickness of 40 μm or greater.

The silver thin film is desirably formed by sputtering a target silver specimen with plasma of an inert gas, and the inert gas is preferably argon or xenon.

Before formation of the silver thin film, the substrate is irradiated with argon ions in the plasma to clean the surface of the substrate.

The silicon nitride film is formed using the chemical vapor deposition by supplying mixture of a gas for plasma generation and ammonia to generate plasma, and exciting silane gas by the plasma to cause the same to react with the ammonia.

The present inventors have also found that a silver thin film which has a (200) plane as a principal plane orientation exhibits an improved reflectivity on a shorter wavelength side of visible light.

The present invention provides a reflector member which comprises a silver thin film having a (200) plane as a principal plane orientation.

Preferably, a ratio of the (200) plane orientation to a (100) plane orientation is 500 or more.

Preferably, the thin film of a silver crystal, having a (200) as a principal plane orientation, is formed on a crystalline substrate, A Si substrate is preferred as the crystalline substrate.

Preferably, the thin film of silver, having a (200) orientation plane as a principal plane orientation, is formed while heating the substrate.

The present invention also provides a backlight unit for use in a liquid-crystal display, the backlight unit employing a reflector member including a silver thin film formed on a substrate and a silicon nitride film formed on the silver thin film.

The present invention also provides a projection-type liquid crystal display device employing a reflector member including a silver thin film formed on a substrate and a silicon nitride film formed on the silver thin film.

The projection-type liquid crystal display device may be a rear-projection-type liquid crystal display device.

The present invention also provides a manufacturing method of a reflector member including a silver thin film formed on a substrate and a silicon nitride film formed on the silver thin film. According to the method, the silver thin film is formed by sputtering a target silver specimen with plasma of an inert gas.

Desirably, the silicon nitride film is formed by the chemical vapor deposition by supplying mixture of a gas for plasma generation and ammonia to generate plasma, and exciting silane gas by the plasma to cause the same to react with the ammonia.

Further, the present invention provides a manufacturing method of a reflector member including a silver thin film formed on a substrate and a silicon nitride film formed on the silver thin film. According to the manufacturing method, using a RF-DC-combined sputtering apparatus including a target and a substrate susceptor arranged in the interior of a processing chamber, a first DC power supply for supplying power to the target, a high-frequency power supply for supplying high frequency waves to the interior of the processing chamber through the target, and a gas supply unit for supplying a plasma generating gas into the processing chamber, an inert gas is supplied to the space between a silver specimen placed at the target and the susceptor to generate plasma, and a silver thin film is formed on the surface of the substrate by sputtering the silver.

The silver thin film is formed with the outputs of the first DC power supply and of the high-frequency power supply adjusted to control the film formation rate of silver deposited on the substrate and the dose of ion irradiation.

Desirably, argon gas or xenon gas is used as the inert gas.

Power is supplied from a second DC power supply via the substrate susceptor to set an argon irradiation energy defined by a difference between the plasma potential and the substrate voltage.

The argon irradiation energy is desirably set to 15 eV or lower.

Preferably, a normalized dose of xenon ion irradiation, that is, a quantity of xenon ions required to deposit one silver atom is set to a range of 1 to 3.

The present invention also provides a reflector member manufacturing method using a microwave plasma processing apparatus including an upper shower plate for emitting plasma excited by microwaves in the form of shower, and a lower shower plate arranged below the upper shower plate so as to face the susceptor and having pipes with a plurality of nozzles for supplying a reactive gas arranged in grid patterns so as to form apertures of a predetermined size. According to the method, plasma is generated with argon gas and ammonia gas supplied from the upper shower plate, after the formation of the silver thin film, and a silicon nitride film is formed on the silver thin film by the reaction between the plasma and silane gas supplied from the lower shower plate.

Desirably, after formation of the silicon nitride film, the supply of silane gas is stopped with the plasma being excited to generate a large quantity of NH radicals, and the NH radicals are applied to the silicon nitride film to form strong silicon-nitrogen bonds.

According to the present invention, the substrate is covered with a silver thin film a large part of which has the (111) plane orientation, whereby high specular reflectance can be realized. Additionally, a thin film of a specific nitride, namely silicon nitride is formed on the silver thin film, whereby a visible-light reflector member having excellent corrosion resistance can be obtained without substantially deteriorating the reflectance.

Further, according to the present invention, a silver thin film is formed by sputtering silver, whereby high reflectance can be realized in a shorter wavelength range of visible light.

Moreover, according to the present invention, high specular reflectance can be realized by forming a silver crystal thin film a large part of which has a (200) plane orientation.

### BRIEF DESCRIPTION OF THE DRAWINGS

FIG. 1 is a cross-sectional view of a visible-light reflector member according to a first embodiment of the present invention;

FIG. 2 is a schematic diagram showing a RF-DC-combined sputtering apparatus used in embodiments of the present invention;

FIGS. 3A and 3B are diagrams showing measurement results of the dependency of the reflectance on the wavelength of light of a silver thin film of a first embodiment of the present invention;

FIG. 4 is a diagram showing the dependency of the reflectance on the film thickness of a silver thin film obtained in the first embodiment of the present invention.

FIG. 5 is a schematic diagram showing a microwave plasma processing apparatus used in formation of a silicon nitride film in embodiments of the present invention;

FIG. 6 is a diagram showing reflectance values of the visible-light reflector member obtained in the first embodiment of the present invention, the reflectance being measured immediately after the film formation, after boiling the same in 100° C. pure water for three hours, and after subjecting the same to a high-temperature/high-humidity test for 1000 hours;

FIG. 7 is a cross-sectional view of a visible-light reflector member according to a second embodiment of the present invention;

FIG. 8 is a diagram showing the dependency of the reflectance at an optical wavelength of 430 nm on the normalized dose of ion irradiation of a silver thin film obtained in the second embodiment of the present invention;

FIG. 9 is a diagram showing the relationship between the normalized dose of ion irradiation and the specific resistance for the cases of using argon gas, krypton gas, and xenon gas in the second embodiment of the present invention;

FIG. 10 is a diagram showing the reflectance values at various wavelengths of a reflector member produced by forming a surface protection film of silicon nitride after formation of the silver thin film according to the second embodiment of the present invention, and the results of a deterioration acceleration test conducted on the reflector member;

FIG. 11A is a diagram showing peaks in the silver plane orientations in a silver thin film formed with the use of a conventional vacuum evaporation apparatus and of a silver thin film formed according to the second embodiment of the present invention, while FIG. 11B is a diagram showing the results of X-ray diffraction analyses conducted on a reflector member fabricated according to the second embodiment, before formation of the surface protection film, after the formation of the surface protection film, and after a deterioration acceleration test (boiling in 100° C. pure water for three hours).

FIG. 12 is a cross-sectional view of a visible-light reflector member according to a third embodiment of the present invention;

FIG. 13 is a diagram showing the dependency of the reflectance of 430 nm wavelength light on the normalized dose of ion irradiation, using the processing chamber pressure as a parameter;

FIG. 14 is a diagram showing the reflectance values at various wavelengths of a reflector member produced by forming a surface protection film of silicon nitride after formation of the silver thin film of the third embodiment of the present invention, and the results of a deterioration acceleration test conducted on the reflector member;

FIG. 15 is a schematic diagram showing an embodiment of a backlight unit for large-size flat-panel liquid crystal display employing the visible-light reflector member of the present invention; and

FIG. 16 is a schematic diagram showing an embodiment of a rear projection television employing the visible-light reflector member of the present invention;

FIG. 17 is a cross-sectional view of a visible-light reflector member according to a fourth embodiment of the present invention;

FIG. 18 is a diagram showing a dependency of the reflectance and X-ray diffraction strength of silver films on the substrate temperature according to the fourth embodiment of the present invention;

FIG. 19 is a diagram showing a dependency of the peak intensity ratio of a (200) plane orientation to a (111) plane orientation of silver films on the substrate temperature according to the fourth embodiment of the present invention; and

FIG. 20 is a diagram showing wavelength dependencies of the reflectance in a room temperature film formation and a 200° C. film formation according to the fourth embodiment of the present invention;

### DESCRIPTION OF THE PREFERRED EMBODIMENTS

The present invention will now be described using embodiments thereof.

### First Embodiment

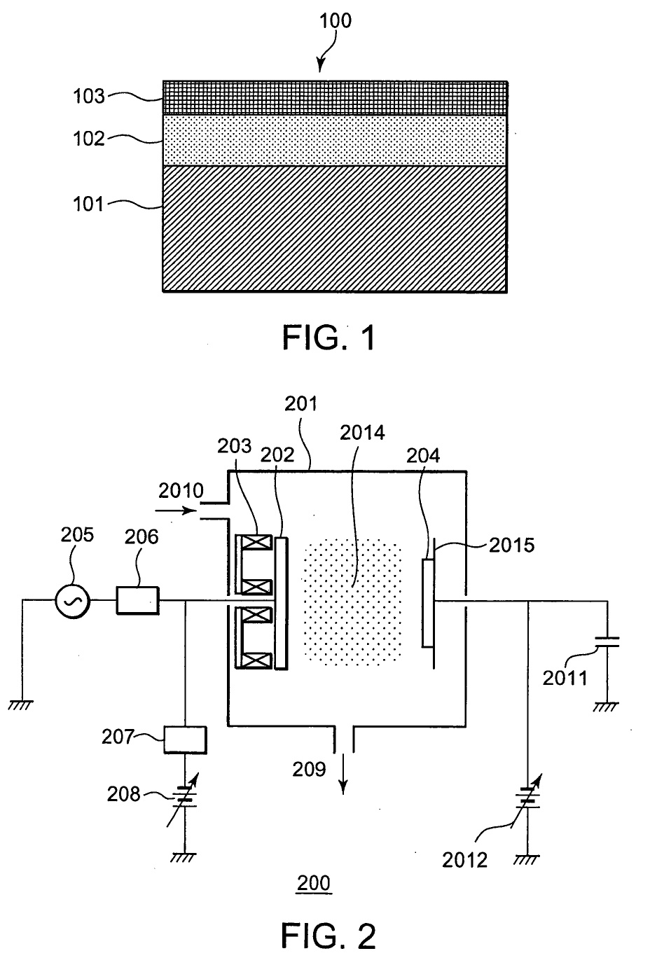

Referring to FIG. 1, a visible-light reflecting plate 100 according to a first embodiment of the present invention has a reflecting layer 102 formed on one surface of a substrate 101. The substrate 101 shown here is formed of a plastic material (specifically, a cycloolefin polymer) having a thickness of 0.7 to 2 mm. The material of the substrate is not limited to a cycloolefin polymer, but metals, glass, ceramics, and other plastic materials may be used. The size or thickness of the substrate is not limited either, but when considering the strength desired for the substrate, the thickness of the substrate is preferably 40 μm or more if the substrate is formed of a flexible material such as resin. When the substrate is formed of a metal, glass, or a ceramic material, the thickness thereof is preferably 100 μm or more. The substrate is formed by flat and/or curved surfaces. The directivity of light is defined by its substantially flat or curved portion. Therefore, the surface roughness of the substrate is preferably one tenth or less of the wavelength 400 nm on the short wavelength side in a visible-light region, namely 40 nm or less, and more preferably one twentieth or less of the wavelength, namely 20 nm or less. A surface protection film 103 of silicon nitride is formed on the reflecting layer 102.

The reflecting layer 102 shown in FIG. 1 is a silver thin film formed by using a RF-DC-combined sputtering apparatus shown in FIG. 2. The steps to form a silver film will be described sequentially with reference to FIG. 2. A silver target 202 is arranged in a processing chamber 201, and a magnet 203 is mounted on the rear of the silver target for efficient plasma excitation. The silver target 202 is connected to a high-frequency power supply 205 via a matching unit 206. The frequency of the high-frequency power supply is selected from the frequencies of 2 to 200 MHz. The frequency is preferred to be as high as possible from the viewpoint of exciting high-density and low-electron-temperature plasma. In this embodiment, the frequency of 100 MHz was used. The silver target 202 is connected not only to the high-frequency power supply but also to a target DC power supply 208 via a high-frequency filter 207, so that a DC voltage can be applied to the silver target. The formation rate of the silver film deposited on the substrate and the dose of ion irradiation to the substrate can be controlled by adjusting the outputs of the target DC power supply 208 and the high-frequency power supply 205.

The processing chamber 201 was evacuated to establish a reduced pressure condition in the interior of the processing chamber 201 by means of a turbo pump (not shown) connected to an exhaust window 209 and a dry pump (not shown) connected in series downstream thereof.

A 2-mm-thick cycloolefin substrate 204 was transferred into a feed chamber (not shown) connected to the processing chamber 201 via a gate valve (not shown). After reducing the pressure in the feed chamber, the gate valve was opened and the substrate was mounted on a stage 2015. The stage 2015 is connected to the surface of the substrate 204 by means of an aluminum claw (not shown), so that the voltage of a DC power supply for substrate 2012 can be applied to the silver surface from the moment when the silver deposition is started even if the substrate is made of an insulator.

After transferring the substrate into the processing chamber 201, argon gas was introduced into the processing chamber through a gas supply port 2010 at a rate of 380 cc/minute to increase the pressure in the interior of the processing chamber to 12 mTorr. The reflectance is reduced if a silver thin film is doped with an impurity contained in the gas. Therefore, the purity of the introduced argon gas is desirably as high as possible. In this example, argon with a water concentration of 1 ppb or less was used.

Before formation of a silver film, it is desirable to clean the substrate surface to remove moisture or an organic substance from the substrate surface. Therefore, in this example, high frequency power of 50 W was applied to the silver target for two minutes to excite plasma 2014, whereby the substrate surface was irradiated with argon ions to remove the moisture and organic substances from the surface.

After the cleaning, the high frequency power supply 205 was set to supply 100 W for 20 seconds while the target DC power supply was set to supply −150V and the substrate DC power supply was set to supply +30V, whereby a quantity of argon ions required to deposit one silver atom to the substrate, that is, the normalized dose of ion irradiation was set to 1.6, and the argon ion irradiation energy defined by a difference between plasma potential and substrate voltage was set to 15 eV. A silver film was formed on the substrate in this condition and the substrate was taken out of the feed chamber. The silver film thickness was found to be 130 nm by using a scanning electron microscope.

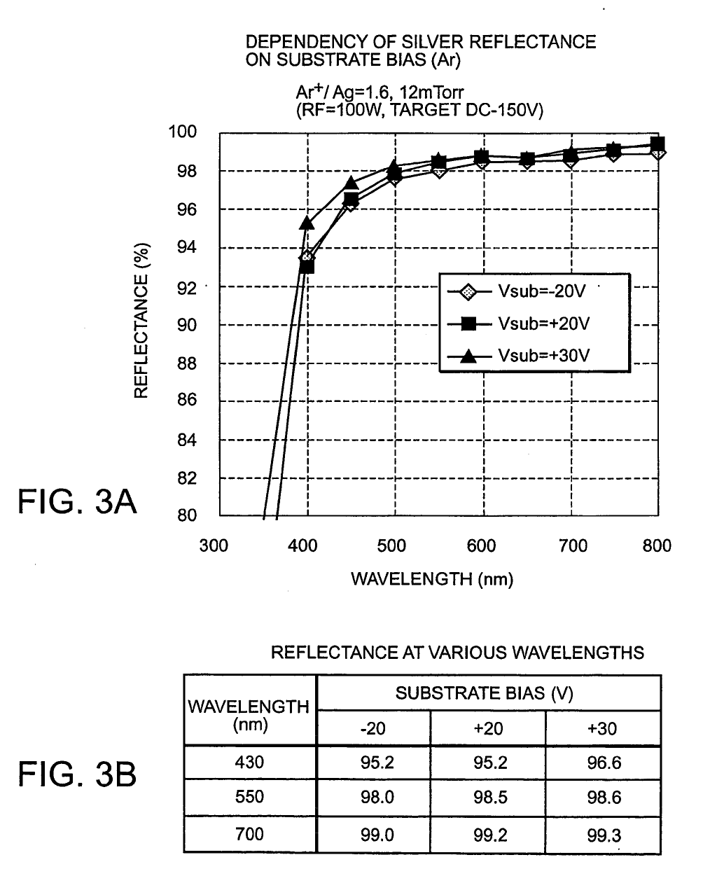

FIGS. 3A and 3B show the measurement results of the dependency of the reflectance on the optical wavelength of a silver thin film which was deposited to a thickness of 130 nm while varying the voltage of the substrate DC power supply by the method as described above. The ion irradiation energy is defined by a difference between plasma potential and substrate bias potential, and thus the ion irradiation energy is reduced as the substrate bias is increased. Since the plasma potential becomes +30 V, +40 V, and +45 V at the substrate bias voltages of −20 V, +20 V, and +30 V, respectively, the ion irradiation energy becomes 50 eV, 20 eV, and 15 eV, respectively. As seen from the results, the silver thin film exhibited a high value of reflectance when the substrate DC power supply voltage was +30 V, that is, when the argon ion irradiation energy was 15 eV or lower.

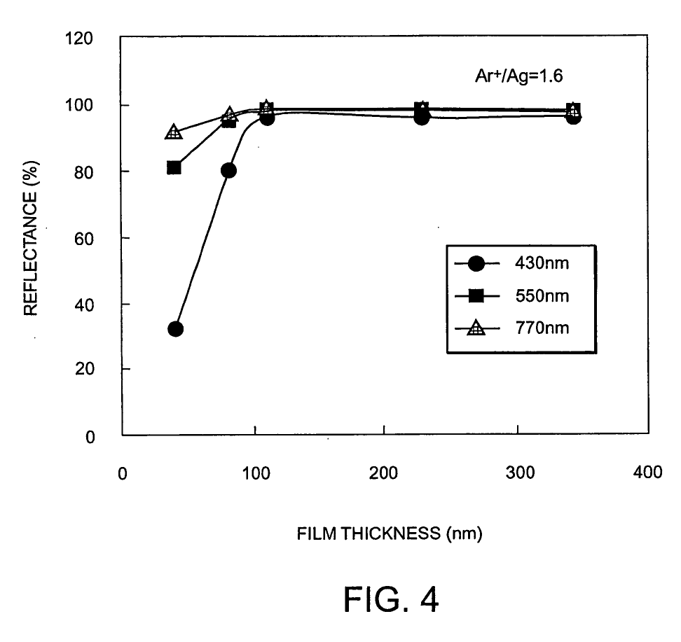

FIG. 4 shows the dependency of the reflectance on the film thickness of the silver thin film (at wavelengths of 430 nm, 550 nm, and 700 nm). The film thickness was controlled by varying the film formation time. As seen from FIG. 4, the reflectance was reduced when the film thickness was 100 nm or thinner, whereas the reflectance was stable when the film thickness was from 100 to 350 nm. Therefore, the film thickness is desirably from 100 to 300 nm in consideration of the cost of silver.

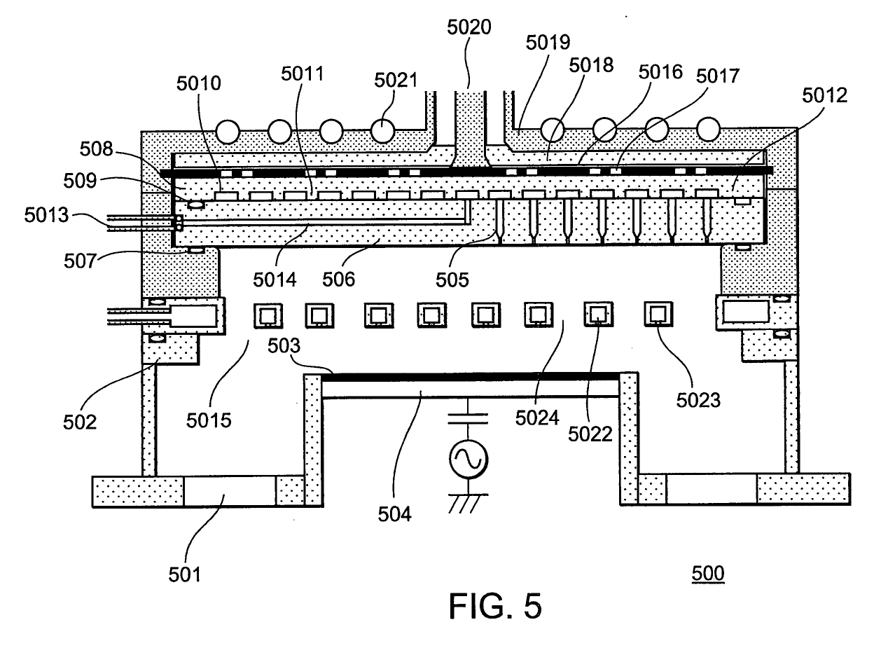

Subsequently, the substrate having a silver thin film formed thereon was taken out of the RF-DC-combined sputtering apparatus, and a surface protection film of silicon nitride was formed with the use of a microwave plasma processing apparatus for plasma CVD shown in FIG. 5. According to the first embodiment, the apparatus for forming a silver thin film and the apparatus for forming a surface protection film are separate and independent from each other. Therefore, in the first embodiment, the substrate was once exposed to atmosphere after the formation of the silver film and before the formation of the nitride film. It is desirable, however, to cluster these two devices together so that the silver and nitride films can be formed consecutively without exposing the substrate to atmosphere.

The steps of forming the surface protection film will be described sequentially with reference to FIG. 5. A microwave plasma processing apparatus shown here has a processing chamber 502 which is evacuated through a plurality of exhaust ports 501. A holding base 504 for holding a substrate to be treated 503 is arranged in the processing chamber 502. For the purpose of uniform evacuation of the processing chamber 502, the processing chamber 502 defines a ring-shaped space around the holding base 504, and the exhaust ports 501 are arranged at regular intervals to communicate with the space, that is, they are arranged in axial symmetry with respect to the substrate to be treated 503. This arrangement of the exhaust ports 501 enables the processing chamber 502 to be evacuated uniformly through the exhaust ports 501.

A planar shower plate 506 is attached, with a seal ring 507 interposed therebetween, to the top of the processing chamber 502 at a position facing the substrate to be treated 503 on the holding base 504, as a part of the external walls of the processing chamber 502. The shower plate 506 is formed of alumina that is a dielectric substance having a low microwave dielectric loss (with a dielectric loss of 1×10₋₄ or less) and is provided with a multiplicity of apertures, namely gas emission holes 505. The processing chamber 502 is further provided with a cover plate 508. The cover plate 508 is attached, with another seal ring 509 interposed therebetween, to the outer side of the shower plate 506, namely to the opposite side of the shower plate 506 relative to the holding base 504. The cover plate 508 is also formed of alumina that is a dielectric substance having a low microwave dielectric loss (with a dielectric loss of 1×10⁻⁴ or less). A space 5010 is formed between the upper surface of the shower plate 506 and the cover plate 508 to be filled with plasma excitation gas. Specifically, the cover plate 508 has a multiplicity of projections 5011 formed on the surface thereof facing the shower plate 506, and the periphery of the cover plate 508 is also provided with a projection ring 5012 protruding flush with the projections 5011. Thus, the space 5010 is formed between the shower plate 506 and the cover plate 508. The gas emission holes 505 are arranged in the space 5010.

A plasma excitation gas supply path 5014 is formed in the interior of the shower plate 506 to communicate with a plasma excitation gas supply port 5013 provided in an external wall of the processing chamber 502. The plasma excitation gas such as argon, krypton, or xenon supplied to the plasma excitation gas supply port 5013 is supplied to the gas emission holes 505 from the supply path 5014 through the space 5010 and introduced into the processing chamber 502.

A radial line slot antenna is arranged on the opposite surface of the cover plate 508 from the one in contact with the shower plate 506, to emit microwaves for plasma excitation. The radial line slot antenna has a structure in which a wave-retardation plate 5018 formed of alumina is sandwiched between a 0.3-mm thick copper plate 5016 having a multiplicity of slits 5017 and an aluminum plate 5019, and a coaxial waveguide 5020 for supplying microwaves is arranged at the center thereof.

Microwaves of 2.45 GHz generated by a microwave power supply (not shown) are supplied to the coaxial waveguide 5020 via an isolator and a matching unit (both not shown), and propagated through the wave-retardation plate 5018 from the center toward the periphery thereof, while being radiated from the slits 5017 to the side of the cover plate 508. As a result, the microwaves are radiated substantially uniformly to the side of the cover plate 508 from the multiplicity of slits 5017. The radiated microwaves are introduced into the processing chamber 502 via the cover plate 506, the space 5010 or the projections 5011, and the shower plate 506. The plasma excitation gas is thus excited by the microwaves and high-density plasma is thereby produced.

In the plasma processing apparatus shown in FIG. 5, a conductor structure 5015 is arranged in the processing chamber 502 between the shower plate 506 and the substrate to be treated 503. This conductor structure 5015 is provided with a multiplicity of nozzles 5023 to which processing gas is supplied from an external processing gas source (not shown) through a processing gas path 5022 formed in the processing chamber 502. The nozzles emit the supplied processing gas to the space between the conductor structure 5015 and the substrate to be treated 503. The conductor structure 5015 is provided with apertures 5024 between the adjacent nozzles, the apertures 5024 having such a size as to allow the plasma excited by the microwaves on the surface of the shower plate 506 facing the conductor structure 5015 to efficiently pass by diffusion to the space between the substrate to be treated 503 and the conductor structure 5015.

When a processing gas is emitted from the conductor structure 5015 configured in this manner to the space through the nozzles, the emitted processing gas is excited by plasma flowing into the space. However, since the plasma excitation gas from the shower plate 506 flows from the space between the shower plate 506 and the conductor structure 5015 towards the space between the conductor structure 5015 and the substrate to be treated 503, little processing gas returns to the space between the shower plate 506 and the conductor structure 5015. This minimizes the decomposition of the gas molecules due to over dissociation caused by exposure to high-density plasma, and minimizes the deterioration in the microwave introduction efficiency due to deposition of the processing gas on the shower plate 506 even if the processing gas is a depositive gas. Accordingly, high-quality substrate processing can be provided.

In this example, the substrate to be treated 503 was placed on the holding base 504, and then argon was introduced through the gas emission holes 505 in the tabular shower plate 506 at a rate of 400 cc/minute to clean the substrate surface. Argon was introduced into the space between the conductor structure 5015 and the substrate to be treated 503 through the nozzles of the conductor structure 5015 at a rate of 120 cc/minute, and the pressure in the interior of the processing chamber was set to 200 mTorr by means of a pressure regulating valve (not shown). Subsequently, 2.45-GHz microwaves of 2 kW were introduced into the coaxial waveguide 5020, and the microwave power was introduced substantially uniformly into the processing chamber 502 through the multiplicity of slits 5017 in the radial line slot antenna to excite the argon plasma for 30 seconds. The argon ions were thus radiated with a low ion irradiation energy, whereby the moisture and the organic substances were removed from the silver surface.

Subsequently, without extinguishing the plasma, that is, without stopping the introduction of argon gas through the gas emission holes 505 of the shower plate 506 and the nozzles of the conductor structure 5015 and without stopping the supply of microwave power, ammonia gas was continuously and additionally introduced through the gas emission holes 505 of the shower plate 506 at a rate of 40 cc/minute while silane gas was introduced through the nozzles of the conductor structure 5015 at a rate of 20 cc/minute, both for 20 seconds. The pressure was set to 200 mTorr. The introduction of silane gas to the diffuse plasma space of a low electron temperature suppressed the overdissociation of silane gas, whereby a high-quality silicon nitride was deposited to a thickness of 8 nm. Subsequently, without extinguishing the plasma, the introduction of silane gas only was stopped and the plasma of argon and ammonia gas was excited for 30 seconds for the purpose of forming strong silicon-nitrogen bonds at the outermost surface of the silicon nitride film. The substrate to be treated was irradiated with a large amount of NH radicals generated by this excitation, whereby the strong silicon-nitrogen bonds were formed on the outermost surface of the substrate to form a surface protection film.

The thickness of the deposited silicon nitride film was varied by the film formation period. As a result, it was found that the reflectance of 430-nm wavelength light was 96.5%, 96.2%, 94.0%, and 90.0%, respectively, when the silicon nitride film thickness was 5 nm, 8 nm, 10 nm, and 15 nm, and thus the reflectance was decreased as the silicon nitride film thickness became thicker. Consequently, it is desirable that the silicon nitride film thickness is as thin as possible so far as the effect of silicon nitride to protect the silver against the corrosion can be obtained. The silicon nitride film thickness is desirably about 8 nm or thinner in order to obtain a reflectance of 96% or more.

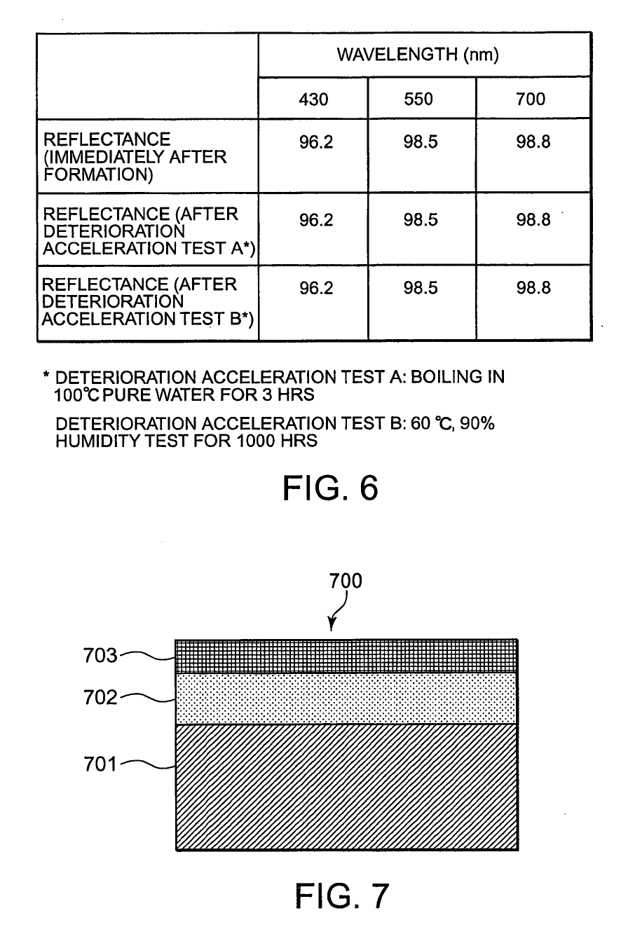

FIG. 6 shows the reflectance values of the reflector member formed in this manner and shown in FIG. 1 at the wavelengths of blue light (430 nm), green light (550 nm), and red light (700 nm). These reflectance values were measured immediately after the formation of the reflector member, after a deterioration acceleration test of boiling the reflector member in 100° C. pure water for three hours, and after another deterioration acceleration test of subjecting the reflector member to high temperature (60° C.) and high humidity (90%) for 1000 hours. As seen from FIG. 6, the reflectance was not deteriorated at all.

It was also recognized that, when the silicon nitride protection film thickness was 5 nm, the reflectance of 430-nm wavelength light was slightly deteriorated from 96.5% to 96.2% after the boiling in 100° C. pure water for three hours, and when no protection film was provided, the reflectance was reduced to 90% or less only by the boiling in 100° C. pure water only for ten minutes. Consequently, the contribution of the protection film to improvement in durability was apparent.

### Second Embodiment

A second embodiment of the present invention will be described with reference to the accompanying drawings. In order to avoid repetition, description of parts and components similar to the counterparts in the first embodiment will be omitted.

Referring to FIG. 7, a visible-light reflecting plate 700 according to the second embodiment of the present invention has a reflecting layer 702 formed on one surface of a substrate 701. The substrate 701 shown here is formed of a plastic material (specifically, a cycloolefin polymer) having a thickness of 0.7 to 2 mm. A surface protection film 703 of silicon nitride is formed on the reflecting layer 702.

The reflecting layer 702 shown here is a silver thin film having the (111) orientation as the principal plane orientation. In the second embodiment, the silver thin film having the (111) orientation as the principal plane orientation was formed by using the RF-DC-combined sputtering apparatus shown in FIG. 2. Xenon gas instead of argon gas was used during the cleaning of the substrate surface and the formation of the silver film. The formation of the silver film was performed with the substrate DC voltage set in an electrically floating state. The setting of the substrate potential to a floating state provides an advantage of eliminating the need of a substrate DC power supply, leading to cost reduction. It also provides an advantage that a stable substrate potential can be easily ensured when the size of a substrate is increased.

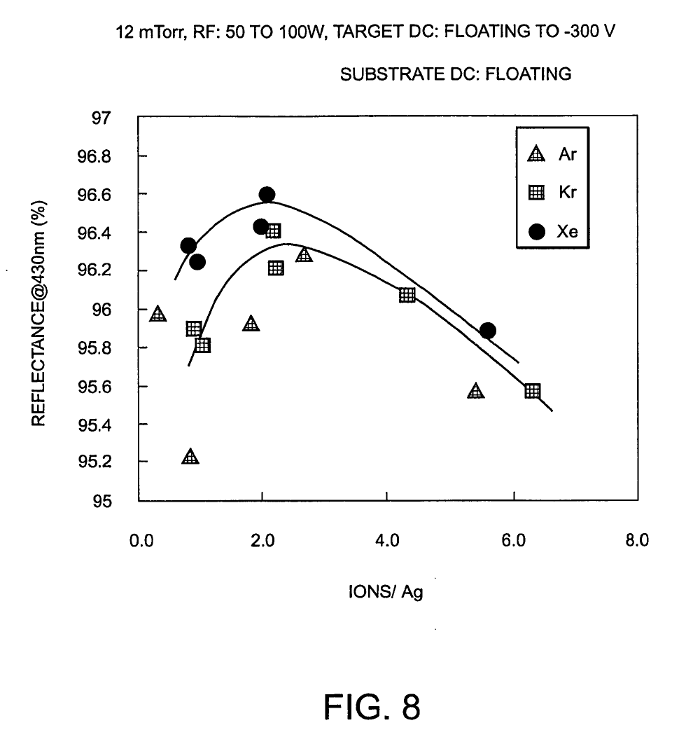

FIG. 8 shows the dependency of the reflectance of 430-nm wavelength light on the normalized dose of ion irradiation for the cases of using argon gas, krypton gas, and xenon gas, respectively. It can be seen that a high reflectance was obtained when xenon gas was used and the normalized dose of ion irradiation was about 2.0.

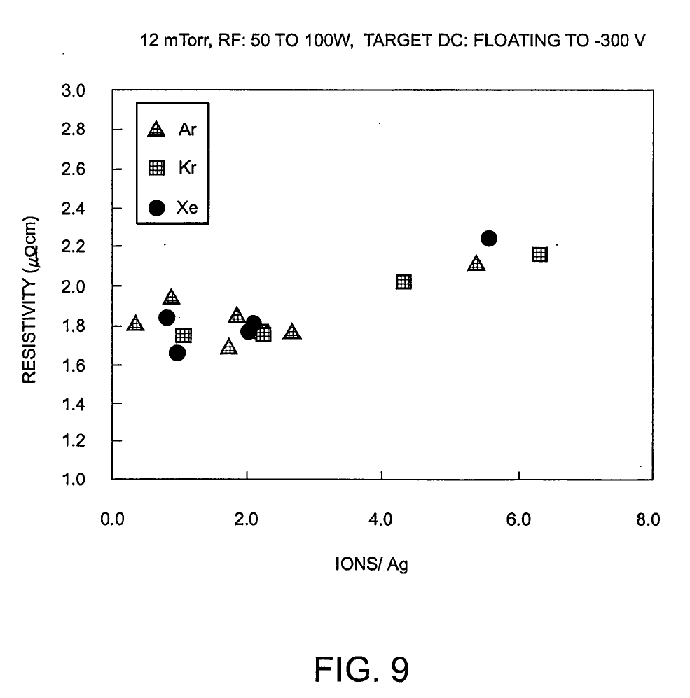

FIG. 9 shows the relationship between the normalized dose of ion irradiation and the specific resistance for the cases of using argon gas, krypton gas, and xenon gas, respectively. The bulk value of silver was 1.59 μΩcm when the dose of normalized ion irradiation was from about 1.0 to 2.0. Accordingly, in this example, the silver thin film was formed with the normalized dose of ion irradiation set to 2.0.

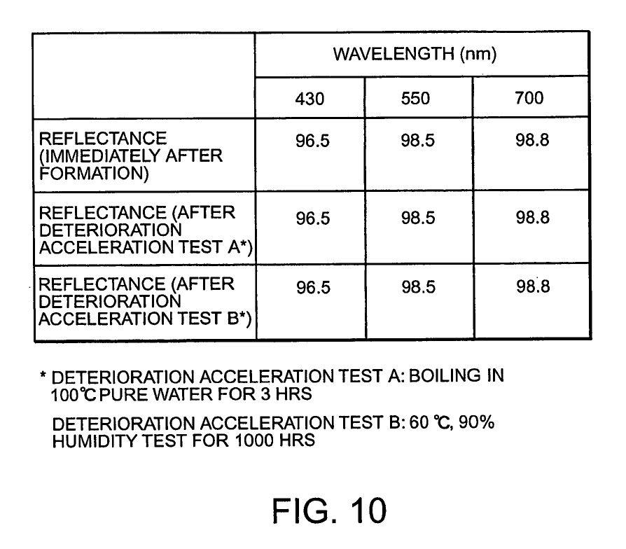

FIG. 10 shows the reflectance values at various wavelengths of a reflector member fabricated by forming a surface protection film of silicon nitride after the formation of the silver thin film, and the results of deterioration acceleration tests of the reflector member. As seen from FIG. 10, the reflector member obtained in this embodiment exhibited high reflectance and was not deteriorated at all.

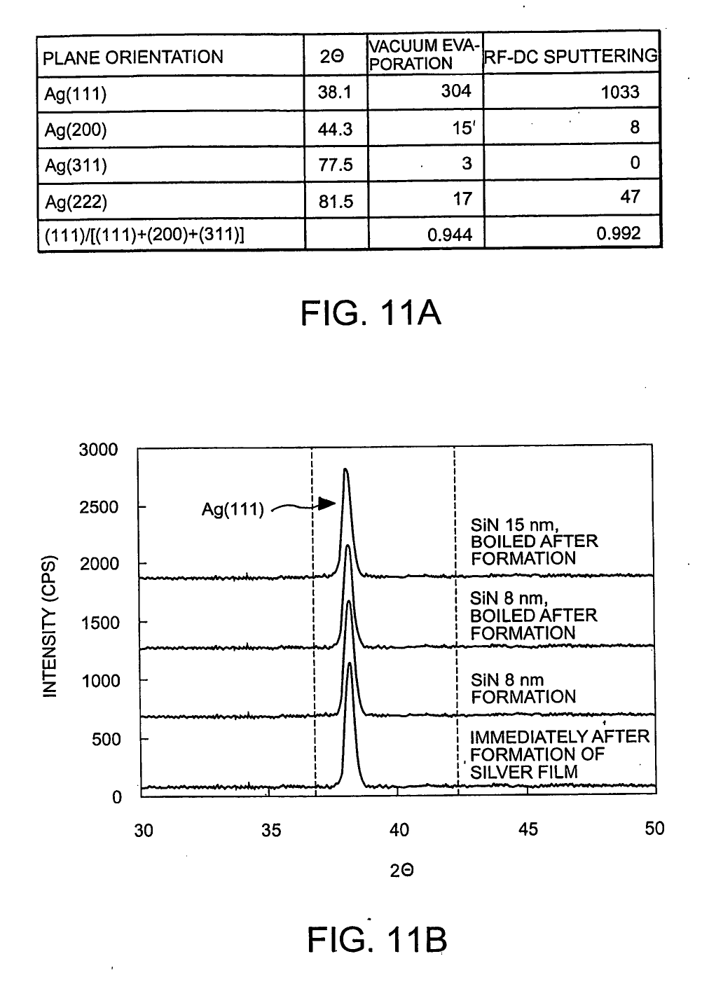

FIG. 11A shows the results of X-ray diffraction analyses conducted on a 130-nm thick silver thin film formed using a conventional vacuum evaporation apparatus, and on a silver thin film formed according to the second embodiment. FIG. 11B shows the results of the X-ray diffraction analyses conducted on the reflector member fabricated in this embodiment before formation of the surface protection film, after formation of the surface protection film, and after subjecting the reflector member to a deterioration acceleration test (of boiling in 100° C. pure water for three hours). As seen from these figures, more than 99% of the silver thin film obtained in this embodiment had the (111) orientation, whereas the vacuum evaporation silver film having the (111) orientation was less than 95%, having the (200), (311) and (222) orientations in addition to the (111) orientation. It was also recognized that more than 99% of the silver film had the (111) plane after the formation of the surface protection film and after the deterioration acceleration test. Thus, it was confirmed that the reflector member obtained was not deteriorated at all.

### Third Embodiment

A third embodiment of the present invention will now be described. In order to avoid repetition, description of parts and components similar to the counterparts in the first and second embodiments is omitted.

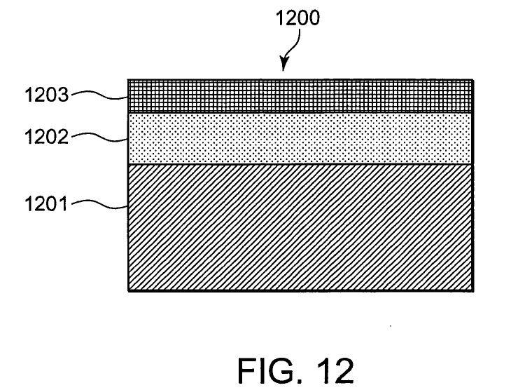

As shown in FIG. 12, a visible-light reflecting plate 1200 according the third embodiment of the present invention has a reflecting layer 1202 formed on one surface of a substrate 1201. The substrate 1201 shown here is formed of a plastic material (specifically, a cycloolefin polymer) having a thickness of 0.7 to 2 mm. A surface protection film 1303 of silicon nitride is formed on the reflecting layer 1202.

The reflecting layer 1202 shown here is a silver thin film having the (111) orientation as the principal plane orientation. The silver thin film having the (111) orientation as the principal plane orientation was formed by using the RF-DC-combined sputtering apparatus shown in FIG. 2. In this embodiment, after the substrate was transferred into the processing chamber, argon gas was introduced into the processing chamber at a rate of 790 cc/minute through the gas supply port 2010 to set the pressure in the interior of the processing chamber to 30 mTorr and the silver thin film was formed.

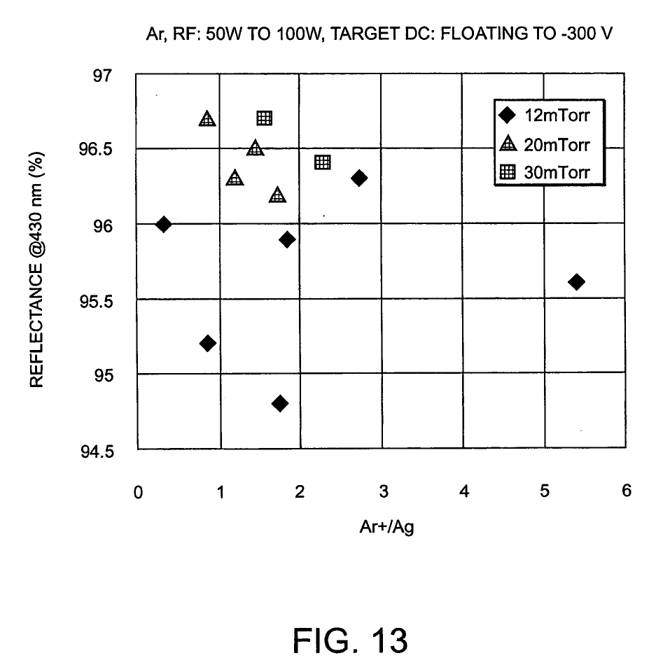

FIG. 13 shows the dependency of the reflectance of 430-nm wavelength light on the normalized dose of ion irradiation, for respective processing chamber pressures of 12 mTorr, 20 mTorr, and 30 mTorr. The substrate potential is set to an electrically floating state. As seen from FIG. 13, when the substrate potential is set to an electrically floating state with argon gas at the pressures of 20 mTorr and 30 mTorr, a high reflectance is obtained when the normalized dose of ion irradiation is about 1 or 2. In this embodiment, a silver thin film was formed with the processing chamber pressure set to 30 mTorr and the normalized dose of ion irradiation set to 1.6. Argon gas is more preferable than xenon gas in view of the cost reduction.

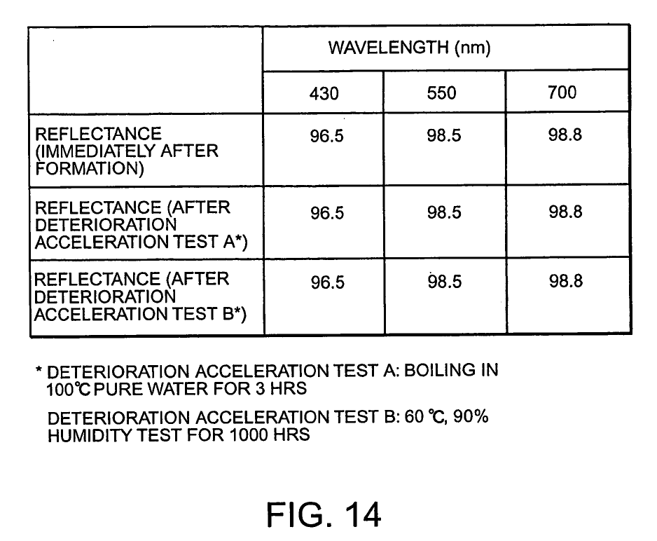

FIG. 14 shows the reflectance values at various wavelengths of a reflector member fabricated by forming a surface protection film of silicon nitride after the formation of the silver thin film, and the results of deterioration acceleration tests of the reflector member. As seen from FIG. 14, the reflector member obtained in this embodiment exhibited high reflectance and was not deteriorated at all.

### Fourth Embodiment

A fourth embodiment of the present invention will be described. In order to avoid repetition, description of parts and components similar to the counterparts in the above-mentioned embodiments will be omitted.

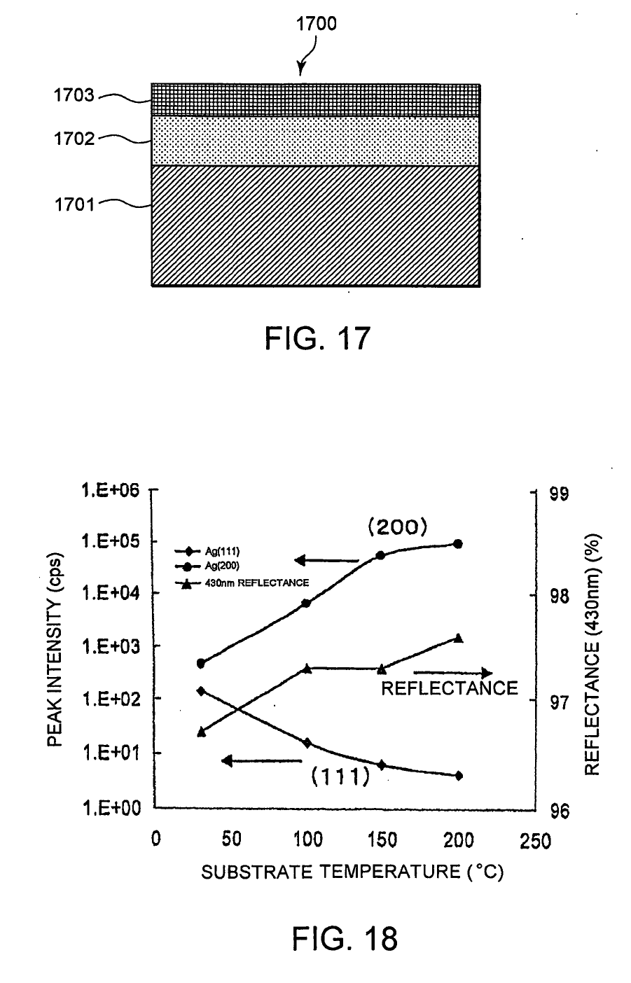

FIG. 17 illustrates a visible-light reflecting plate of the fourth embodiment which uses Si as a substrate 1701.A surface protection film 1703 is a silicon nitride film. A reflecting layer 1702 is made of a silver film in which a crystal structure of silver has mainly a (200) plane orientation in this embodiment.

A film is formed with a thickness of 300 nm by sputtering a silver target while heating a Si substrate. The target is made of pure silver having a diameter of 2 inches. The substrate is made of a silicon wafer of a 25 mm×25 mm square. Under an argon pressure of 12 mTorr, a DC voltage of −150V and a high frequency RF power of 100 W at 100 MHz are supplied to the target while the Si substrate is kept floating.

The characteristics of the reflection films which are obtained by varying substrate heating temperature have been examined. Such characteristics are shown in FIG. 18 in which a right vertical line represents the reflectance at a wavelength of 430 nm. As apparent from the drawing, the heating improves the reflectance in shorter wavelengths, and particularly better improvements are seen above a temperature of 100° C.

In the drawing, the dependency of the peak strengths in X-ray diffraction of silver films (in left vertical line) on the substrate temperature is also shown. These peaks are those from the (200) orientation plane and the (100) orientation plane.

It is considered that the enhancement above 100° C. of the reflectance comes from the increase in a ratio of the (200) plane orientation.

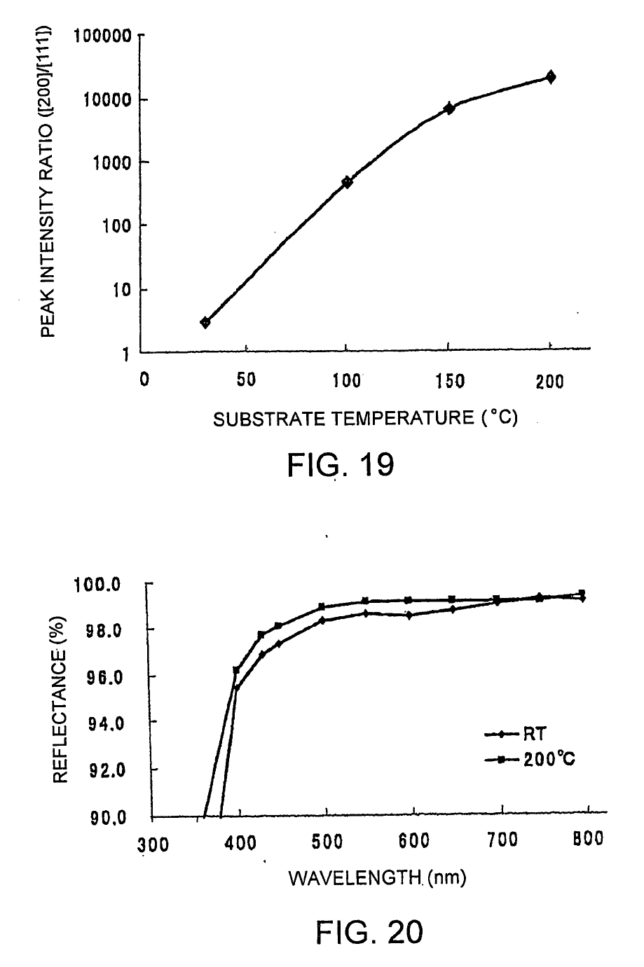

FIG. 19 shows a dependency of the peak intensity ratio of a (200) plane orientation to a (111) plane orientation on the substrate temperature. As seen from FIGS. 18 and 19, the ratio of the (200) plane orientation to the (111) plane orientation at 100° C., at which improvements are particularly observed, is about 500. Thus, it is preferred that the film is formed under such a condition that the ratio of 500 or more can be achieved.

FIG. 20 shows wavelength dependencies of the reflectance in a room temperature film formation and a 200° C. film formation. It is seen that the film formed at 200° C. has a less reduction in reflectance on the side of shorter wavelengths due to the greater ratio of the (200) plane orientation compared with the room temperature film formation.

In the sputtered silver film, the sputtered particles arrive at the substrate and then gain heat energy due to the elevated substrate temperature, migrate, and orient to have the (200) plane orientation. Particularly, in the crystalline substrate such as a Si substrate, it is considered that the film is more likely to have the (200) orientation under the influence of the orientation of the substrate, leading to an increased reflectance.

Although the Si substrate is used in the above example, even in a substrate made of an amorphous material such as a glass substrate, the enhancement of the substrate temperature and the resultant increase in the ratio of the (200) orientation plane in the silver crystal structure may lead to increase the reflectance.

### Fifth Embodiment

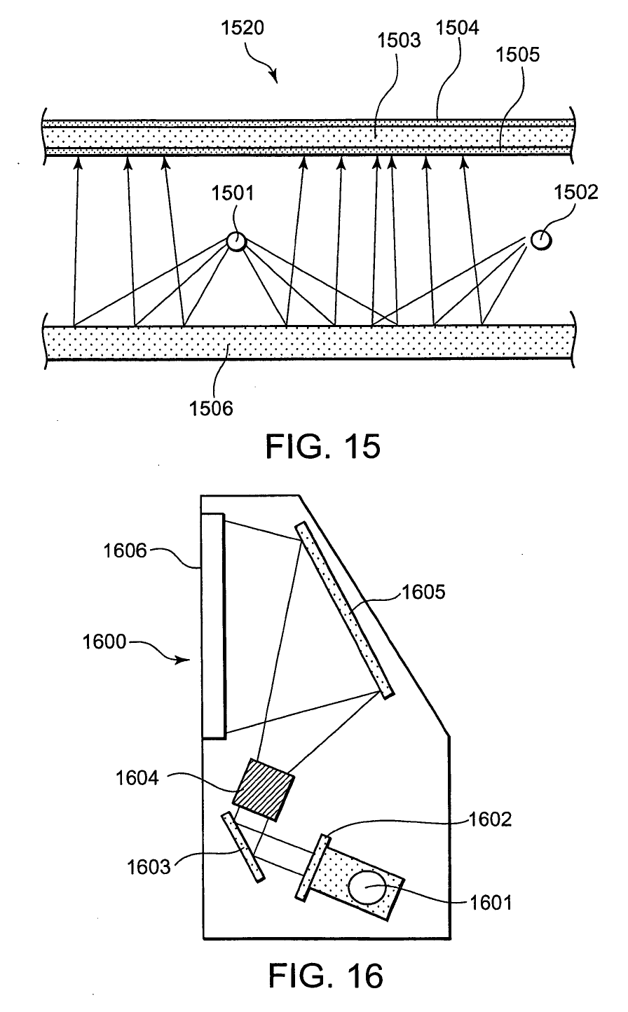

An embodiment of a backlight unit for large-size flat-panel liquid crystal display employing a visible-light reflector member of the present invention will be described with reference to FIG. 15. The backlight unit 1520 has cold cathode fluorescent lamps (CCFLs) 1501 and 1502, a diffusion plate 1503 placed above the CCFLs 1501 and 1502 at a distance therefrom, and diffusion paint layers 1504 and 1505 formed on both surfaces of the diffusion plate 1503. A visible-light reflector member 1506 according to the present invention is arranged to face the diffusion plate 1503 across the CCFLs 1501 and 1502. In this embodiment, in order to give light directivity to a reflector member to be produced, a substrate formed of a plastic material having a Fresnel structure in which notches with a width of several micrometers were formed on the surface thereof was used, and a reflecting layer consisting of a silver thin film and a surface protection film of silicon nitride were formed on the substrate. It will be apparent that, in order to give light directivity to the reflector member, a substrate having a surface structure other than the Fresnel structure can be used. It is desirable, however, that the surface structure be such that every portion of the substrate surface can be subjected to irradiation of ions during formation of the silver film and silicon nitride film thereon with the plasma getting into and contacting the uneven portion of the substrate surface.

In the backlight unit 1520 shown in FIG. 15, light beams from the CCFLs 1501 and 1502 adjacent to each other are reflected by a reflector member 1506 as indicated by the arrows. Further, this visible-light reflector member 1506 having a Fresnel structure reflects light beams in a similar manner to a concave mirror. Therefore, the reflected light is incident on the diffusion plate 1503 without being spread and even brighter full-area light can be obtained. Accordingly, the backlight unit shown in FIG. 15 is optimum as a reflecting plate for use in a large-size flat-panel liquid crystal display backlight unit. Furthermore, the required number of CCFLs can be decreased in comparison with the prior art, and thus the energy consumption of the display can be reduced.

### Sixth Embodiment

Referring to FIG. 16, an embodiment of a rear projection television 1600 employing a visible-light reflector member of the present invention will be described. Light emitted by a light source 1601 consisting of a high-pressure mercury lamp is converted into a blue, green and red light flux by means of a liquid-crystal panel 1602. This light flux is reflected by a first visible-light reflector member 1603 and incident on a projector lens 1604. The first visible-light reflector member 1603 has a substrate formed of a cycloolefin polymer, a reflecting layer consisting of a silver thin film, and a surface protection layer formed of silicon nitride. The light flux enlarged by the projector lens 1604 is directed to a projection screen 1606 by a second visible-light reflector member 1605, and converted into an image. The second visible-light reflector member 1605 has a substrate formed of a cycloolefin polymer, a reflecting layer consisting of a silver thin film, and a surface protection layer of silicon nitride. In the rear projection television according to the embodiment, the loss of light by the reflector member was reduced. Thus, the improvement in brightness of television images and the reduction of power consumption could be realized.

Although the reflecting film of the present invention is described in connection with the application to a backlight for a flat display and a rear projection television in the fifth and six embodiments, it is not restricted to such applications and is also applicable to a reflector for vehicle head lights, a reflector for projector lamps, a reflector for mirror projection aligners, and a reflector for multiple reflection optical instruments.

What is claimed is:

1. A reflector member comprising a silver thin film formed on a substrate and a silicon nitride film formed on the silver thin film.

2. The reflector member according to claim 1 wherein the silver thin film comprises a (111) orientation as a principal plane orientation.

3. The reflector member according to claim 2, wherein 99% or more of the silver thin film has the (111) orientation as the principal plane orientation.

4. The reflector member according to claim 1 wherein the silver thin film has a reflectance of 96% or higher at a wavelength of 430 nm.

5. The reflector member according to claim 1, wherein the silver thin film has a film thickness in the range of 100 nm to 350 nm.

6. The reflector member according to claim 1, wherein the silicon nitride film has a film thickness of 5 nm to 8 nm.

7. The reflector member according to claim 1, wherein the substrate is made of a plastic material having a thickness of 0.7 mm to 2 mm.

8. The reflector member according to claim 1, wherein the substrate is made of a flexible resin.

9. The reflector member according to claim 8, wherein the substrate has a thickness of 40 μm or greater.

10. The reflector member according to claim 1, wherein the silver thin film is formed by sputtering a target silver specimen with plasma of an inert gas.

11. The reflector member according to claim 10, wherein the inert gas is argon.

12. The reflector member according to claim 10, wherein the inert gas is xenon.

13. The reflector member according to claim 11, wherein the substrate is irradiated with argon ions in the plasma to clean the substrate surface before the silver thin film is formed thereon.

14. The reflector member according to claim 1, wherein the silicon nitride film is formed by chemical vapor deposition by supplying a mixture of a gas for plasma generation and ammonia to generate plasma, and exciting silane gas by the plasma to cause the same to react with the ammonia.

15. The reflector member according to claim 1, wherein the silver thin film comprises a (200) plane orientation as a principal plane orientation.

16. The reflector member according to claim 15, wherein the silver thin film further comprises a (100) plane orientation and a ratio of the (200) plane orientation to the (100) plane orientation is 500 or more.

17. The reflector member according to claim 15, where the substrate comprises a Si substrate or non-crystallized materials.

18. A backlight unit, wherein the reflector member according to claim 1 is employed as a reflector member of the backlight unit for use in a liquid-crystal display.

19. The backlight unit according to claim 18, wherein the substrate has a Fresnel structure.

20. A projection-type liquid crystal display device, wherein the reflector member according to claim 1 is employed as a reflector member of the projection-type liquid crystal display device.

21. The projection-type liquid crystal display device according to claim 20, wherein the projection-type liquid crystal display device is of a rear-projection type.

22. A reflector for use in a vehicle head light, wherein the reflector member according to claim 15 is employed.

23. A reflector for use in a projector, wherein the reflector member according to claim 15 is employed.

24. A reflector for use in a mirror projection aligner, wherein the reflector member according to claim 15 is employed.

25. A reflector for use in a multiple reflection optical instrument, wherein the reflector member according to claim 15 is employed.

26. A manufacturing method of a reflector member comprising the steps of: forming a silver thin film on a substrate; and forming a silicon nitride film on the silver thin film, wherein the silver thin film is formed by sputtering a target silver specimen with plasma of an inert gas.

27. The reflector member manufacturing method according to claim 26, wherein the silicon nitride film is formed by chemical vapor deposition by supplying a mixture of a gas for plasma generation and ammonia to generate plasma, and exciting a silane gas by the plasma to cause the same to react with the ammonia.

28. A manufacturing method of a reflector member comprising the steps of: forming a silver thin film on a substrate; and forming a silicon nitride film on the silver thin film, wherein, using a RF-DC-combined sputtering apparatus comprising a target and a substrate susceptor arranged in the interior of a processing chamber, a first DC power supply for supplying power to the target, a high-frequency power supply for supplying high frequency waves to the interior of the processing chamber through the target, and a gas supply unit for supplying a plasma generating gas into the processing chamber, an inert gas is supplied to a space between a silver specimen placed at the target and the susceptor to generate plasma, and a silver thin film is formed on the surface of the substrate by sputtering the silver specimen.

29. The reflector member manufacturing method according to claim 28, wherein the silver thin film is formed with the outputs of the first DC power supply and of the high-frequency power supply adjusted to control the film formation rate of silver deposited on the substrate and the dose of ion irradiation.

30. The reflector member manufacturing method according to claim 28, wherein argon is used as the inert gas.

31. The reflector member manufacturing method according to claim 30, wherein before the formation of the silver thin film on the substrate, argon plasma is generated in the interior of the processing chamber and the substrate surface is cleaned by being irradiated with argon ions.

32. The reflector member manufacturing method according to claim 31, wherein power is supplied from a second DC power supply via the substrate susceptor to set an argon irradiation energy defined by a difference between a potential of the plasma and a voltage of the substrate.

33. The reflector member manufacturing method according to claim 32, wherein the argon irradiation energy is set to 15 eV or lower.

34. The reflector member manufacturing method according to claim 29, wherein xenon is used as the inert gas.

35. The reflector member manufacturing method according to claim 33, wherein the silver film is formed while a normalized dose of xenon ion irradiation, that is, a quantity of xenon ions one silver atom is deposited with is in a range from 1 to 3.

36. The reflector member manufacturing method according to claim 28, wherein after the formation of the silver thin film, using a microwave plasma processing apparatus including an upper shower plate for emitting plasma excited by microwaves in the form of shower, and a lower shower plate arranged below the upper shower plate so as to face the susceptor and having pipes with a plurality of nozzles for supplying a reactive gas arranged in grid patterns so as to form apertures of a predetermined size, plasma is generated with an argon gas and an ammonia gas supplied from the upper shower plate, and a silicon nitride film is formed on the silver thin film by reaction between the plasma and silane gas supplied from the lower shower plate.

37. The reflector member manufacturing method according to claim 36, wherein after formation of the silicon nitride film, the supply of silane gas is stopped with the plasma being excited to generate a large quantity of NH radicals, and the NH radicals are applied to the silicon nitride film to form strong silicon-nitrogen bonds.
